(19) United States
(12) Patent Application Publication
(10) Pub. No.: US 2004/0146744 A1
(43) Pub. Date: Jul. 29, 2004

(54) Material for an electroluminescence element and electroluminescence element using the same

(76) Inventors: Satoshi Seo, Kawasaki (JP); Hiroko Yamazaki, Atsugi (JP)

Correspondence Address: FISH & RICHARDSON P.C., 1425 K STREET, N.W., 11TH FLOOR, WASHINGTON, DC, 20005-3500, US

(21) Appl. No.: 10/622,504

(22) Filed: Jul. 21, 2003

(30) Foreign Application Priority Data
Jul. 31, 2002 (JP) 2002-222451

(51) Int. Cl. B32B 9/00

(52) U.S. Cl. 428/690

(57) ABSTRACT

To provide a material for an electroluminescence element of which a buffer layer can be formed without using water as a solvent unlike a conventional polymer material used in a buffer layer, and an electroluminescence element using the same. According to the present invention, in an electroluminescence (EL) element including a first electrode (101), a buffer layer (102), an electroluminescence (EL) film (103), and a second electrode (104) (as shown in FIG. 1A), a conductive material is used as the buffer layer (102) formed on the first electrode (101). The conductive material includes: a polymer compound (so-called conjugate polymer) soluble in an organic solvent, which has a conjugate on a main or side chain thereof; and a compound soluble in an organic solvent, which has acceptor or donor properties for the polymer compound.

### BACKGROUND OF THE INVENTION

1. Field of the Invention

The present invention relates to an electroluminescence (EL) element capable of emitting fluorescence or phosphorescence by applying an electric field to an element, in which an organic compound-containing film (hereinafter, referred to as electroluminescence (EL) film) is formed between a pair of electrodes. In particular, the present invention relates to an electroluminescence element using a conductive polymer material (material for an electroluminescence element) in part of the element.

2. Description of the Related Art

Heretofore, electroluminescence elements, in which phosphors are made of materials having characteristics such as being self-luminous, thin and lightweight, and capable of high-speed response and DC low-voltage drive, have been expected to be applied in next-generation flat panel displays, in particular, those of portable devices. Furthermore, a light-emitting device, in which electroluminescence elements are arranged in a matrix form, provides a wide view angle. Therefore, such a light-emitting device has been considered as one superior to the conventional liquid crystal display device in terms of visibility.

The light-emitting mechanism of the electroluminescence element is as follows. In the electroluminescence element, an electroluminescence film is sandwiched between a pair of electrodes (cathode and anode). When a voltage is applied between the electrodes, an electron injected from the cathode and a hole injected from the anode are recombined at the luminescent center in the electroluminescence film to allow the formation of a molecular exciton. Therefore, it is assumed that light is emitted as a result of releasing energy when the molecular exciton returns to a base state. There are known two different excitation states, a singlet excitation state and a triplet excitation state. Luminescence may be caused through either of the states.

In the case of applying such a light emitting device to a portable device, low power consumption is required. Therefore, a reduction in drive voltage of the electroluminescence element is an important challenge to be addressed.

Conventionally, as one of techniques for reducing the drive voltage, an attempt has been made to form a buffer layer on a boundary surface between the electrode and the electroluminescence film. The buffer layer may be either of a low molecular weight material or a high molecular weight material (i.e., polymer material). In the case of using the low molecular weight material, more specifically, it has been reported that the buffer layer using high molecular weight aryl amines referred to as starburst amines represented by copper phthalocyanine (Cu-Pc) and m-MTDATA may be formed on a boundary surface between the electroluminescence film and the anode (Document 1: Y Shirota, Y Kuwabara, H. Inada, T. Wakimoto, H. Nakada, Y. Yonemoto, S. Kawami, and K. Imai, Appl. Phys. Lett., 65, pp. 807 (1994)). In addition, each of these materials has a high HOMO energy level comparable to the work function of the electrode material for forming an anode, so that a reduction in hole-injection barrier can be attained.

Furthermore, in the case of using the polymer material, the use of polyethylene dioxythiophene (PEDOT) as the buffer layer at the boundary surface between the electroluminescence film and the anode has been reported as an example (Document 2: J. M. Bharathan and Y Yang: Appl. Phys. Lett., 72, pp. 2660 (1998)). Furthermore, in general, PEDOT is doped with polystyrene sulfonate (PSS) to thereby exhibit conductivity that enables the function of the conductive polymer.

In the case of using the polymer material, furthermore, a buffer layer made of the conductive polymer having a large contact area with the electrode is formed on the electrode. Therefore, the adhesion to a light emitting layer formed on the electrode through the buffer layer can be increased, so that hole-injection efficiency can be improved, resulting in a reduction in drive voltage.

Recently, furthermore, there is also reported a method including forming a radical cation by the action of an inorganic material to function as a Lewis acid on a triphenylamine derivative provided as a polymer material to prepare a layer having an increased conductivity for use in the boundary surface with the electrode (Document 3: A. Yamamori, C. Adachi, T. Koyama, and Y. Taniguchi, Appl. Phys. Lett., 72, pp. 2147-2149 (1998)).

Comparing with the low molecular weight material, the polymer material is easy to handle with a high heat resistance. Therefore, the polymer material is a preferable material for the formation of a buffer layer. In the case of using PEDOT as such a polymer material, an organic sulfonic acid is used as a dopant for obtaining the conductivity, so that the use of water as a solvent would be an indispensable condition.

However, it has been known that the electroluminescence element is typically deteriorated significantly in the presence of water. For improving the reliability of the electroluminescence element, it has been desired to prepare a buffer layer using a polymer material without the need of water to be provided as a solvent.

Furthermore, for providing the polymer material with conductivity, there is a method of using an inorganic material as a dopant, as described above. In this case, however, it is industrially unpreferable because of the need of using a material such as antimony (Sb) which is detrimental to the environment.

### SUMMARY OF THE INVENTION

It is an object of the present invention to provide an environmentally friendly material for an electroluminescence element (hereinafter, referred to as EL element), of which a buffer layer can be formed without using water as a solvent and which is different from the conventional polymer material used for the buffer layer. It is another object of the present invention to provide an electroluminescence element capable of improving a property of carrier injection from the electrode by use of the material for the electroluminescence element while decreasing a drive voltage of the element in addition to increasing reliability of the element.

For solving the above problems, as shown in FIG. 1A, in an electroluminescence (EL) element including a first electrode 101, a buffer layer 102, an electroluminescence (EL) film 103, and a second electrode 104, the inventors of the present invention have found the use of a novel conductive material as the buffer layer 102 formed on the first electrode 101. The conductive material includes: a polymer compound (so-called conjugate polymer compound) soluble in an organic solvent, which has a conjugate on its main or side chain; and a compound soluble in an organic solvent, which has acceptor or donor properties for the polymer compound.

Features of the preparation of the buffer layer 102 of the present invention reside in the use of a nonprotic or neutral compound for the compound soluble in an organic solvent, which has the acceptor or donor properties. Furthermore, the conjugate polymer compound may be any compound as far as it can be dissolved in an organic solvent. In particular, it is preferable to use a redox polymer (oxidation-reduction polymer) which allows the formation of a buffer layer having a high property of hole injection from an anode or the formation of a buffer layer having a high property of electron injection from the cathode by doping an acceptor compound or a donor compound.

Furthermore, the above polymer compound (conjugate polymer) soluble in the organic solvent, which has a conjugate on its main or side chain includes a lower polymer (oligomer) in which the number of repetitive structural units (polymerization degree) is about 2 to 20.

Here, reaction to be caused in the buffer layer 102 of the present invention is shown in FIG. 1B. When the buffer layer 102 is constructed of a conjugate polymer and an acceptor compound (in the figure, abbreviated to acceptor), the acceptor compound pulls electrons out of the conjugate polymer. As a result, the conjugate polymer stands as a carrier (hole). In this case, that is, an electrode provided in contact with the buffer layer 102 becomes an anode. On the other hand, when the buffer layer 102 is constructed of a conjugate polymer and a donor compound (in the figure, abbreviated to donor), the donor compound provides the conjugate polymer with electrons. As a result, the conjugate polymer stands as a carrier (electron). In this case, that is, an electrode provided in contact with the buffer layer 102 becomes a cathode.

FIG. 1C is a conceptual view for illustrating the case in which the buffer layer 102 is constructed of a conjugate polymer and an acceptor compound. In this case, the first electrode (anode) 101 pulls an electron out of the acceptor level present in the conjugate polymer and simultaneously a hole is brought into the acceptor level by injecting into the buffer layer 102. Furthermore, the injected hole moves to the HOMO level in the buffer layer 102. Subsequently, the hole moves to the HOMO level in the electroluminescence film 103. In this case, the movement of the hole from the first electrode 101 to the buffer layer 102 occurs at places with little energy difference, so that such a movement can easily occur. In addition, comparing with direct injection from the first electrode 101, the energy difference is relaxed when the injected hole moves from the acceptor level to the HOMO level in the electroluminescence film 103. Therefore, the properties of hole injection from the first electrode can be improved.

FIG. 1D is a conceptual view for illustrating the case in which the buffer layer 102 is constructed of the conjugate polymer and the donor compound. In this case, from the first electrode (cathode) 101, an electron is injected to the donor level present in the conjugate polymer. Furthermore, the injected electron moves to the LUMO level in the buffer layer 102. Subsequently, the electron moves to the LUMO level in the electroluminescence film 103. In this case, the movement of the electron from the first electrode 101 to the buffer layer 102 occurs at places with little energy difference, so that such a movement can easily occur. In addition, comparing with a direct injection from the first electrode 101, the energy difference is relaxed when the injected electron moves from the LUMO level in the buffer layer 102 to the LUMO level in the electroluminescence film 103. Therefore, the properties of electron injection from the first electrode 101 can be improved.

According to a structure of the present invention, there is provided a material for an electroluminescence element, including a combination of: a polymer compound having a conjugate on its main chain or side chain; and at least one selected from compounds having acceptor properties and represented by the following respective general formulae (1) to (7).

[General Formula 1]

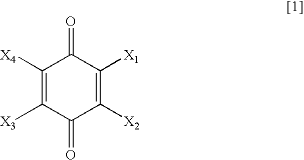

(X1 to X4: hydrogen atom, halogen atom or cyano group)

[General Formula 2]

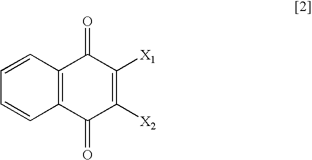

(X1 and X2: hydrogen atom, halogen atom or cyano group)

[General Formula 3]

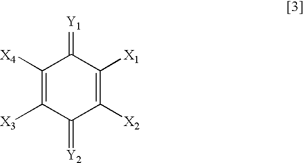

(X1 to X4: hydrogen atom, halogen atom or alkyl group

Y1 to Y2: dicyanomethlene group or cyanoimino group)

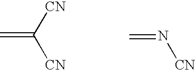

[General Formula 4]

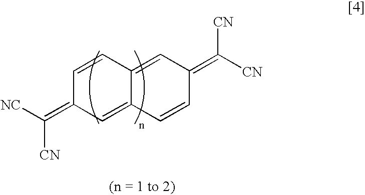

[General Formula 5]

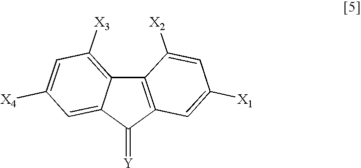

(X1 to X4: hydrogen atom or nitro group

Y: oxygen atom or dicyanomethylene group)

[General Formula 6]

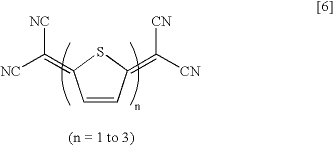

[General Formula 7]

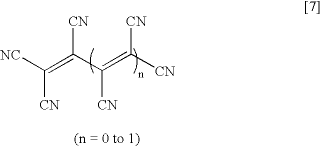

According to another structure of the present invention, there is provided a material for an electroluminescence element, including a combination of: a polymer compound having a conjugate on its main chain or side chain; and at least one selected from compounds having donor properties and represented by the following respective general formulae (8) to (11).

[General Formula 8]

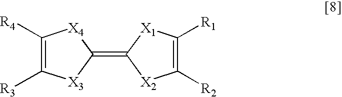

(X1 to X4: S, Se, or Te

R1 to R4: hydrogen atom, or alkyl group, or R1 and R2, or R3 and R4 may be connected with each other and form alkylene chain or condensed ring)

[General Formula 9]

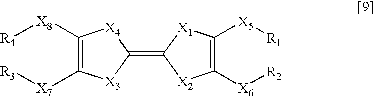

(X1 to X8: S, Se, or Te

R1 to R4: hydrogen atom, or alkyl group, or R1 and R2, or R3 and R4 may be connected with each other and form alkylene chain or olefin double bond)

[General Formula 10]

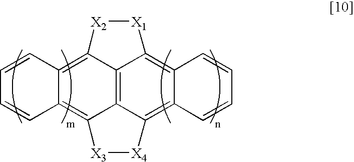

(X1 to X4: S, Se, or Te

n and m=0 to 1)

[General Formula 11]

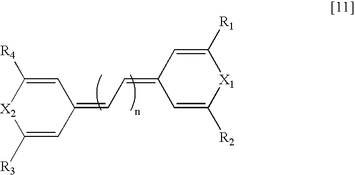

(X1 and X2: S, Se, or Te

R1 to R4: hydrogen atom, alkyl group, aryl group

n=0 to 1)

According to another structure of the present invention, there is provided an electroluminescence element having an anode, a buffer layer, an electroluminescence layer, and a cathode, in which the buffer layer formed in contact with the anode is made of a material for the electroluminescence element, and the material includes a combination of: a polymer compound having a conjugate on its main chain or side chain; and at least one selected from compounds having acceptor properties and represented by the above respective general formulae (1) to (7).

According to another structure of the present invention, there is provided an electroluminescence element having an anode, a buffer layer, an electroluminescence layer, and a cathode, in which the buffer layer formed in contact with the cathode is made of a material for the electroluminescence element, and the material includes a combination of: a polymer compound having a conjugate on its main chain or side chain; and at least one selected from compounds having donor properties and represented by the above respective general formulae (8) to (11).

### BRIEF DESCRIPTION OF THE DRAWINGS

In the accompanying drawings:

FIGS. 1A to 1D are schematic diagrams for illustrating a configuration of an electroluminescence (EL) element in accordance with the present invention;

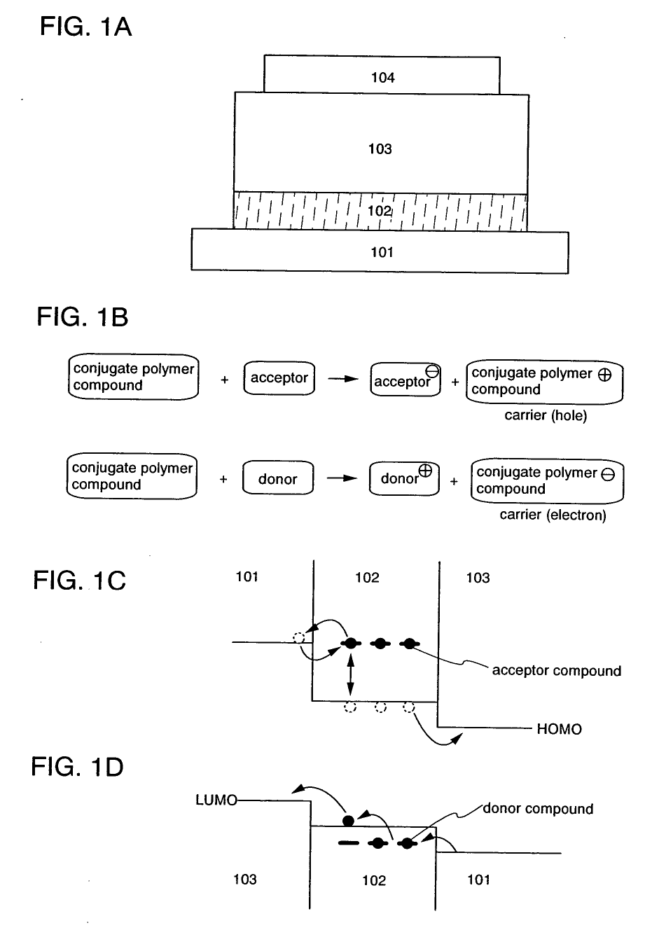

FIGS. 2A and 2B are schematic diagrams for illustrating a configuration of an electroluminescence (EL) element having a buffer layer on an anode side in accordance with the present invention;

FIGS. 3A and 3B are schematic diagrams for illustrating the configuration of an electroluminescence (EL) element having a buffer layer on a cathode side in accordance with the present invention; and

FIG. 4 is a graph for illustrating measurements on electrical characteristics of an electroluminescence element.

### DETAILED DESCRIPTION OF THE PREFERRED EMBODIMENTS

Hereinafter, preferred embodiments of the present invention will be described with reference to the accompanying drawings.

[Embodiment 1]

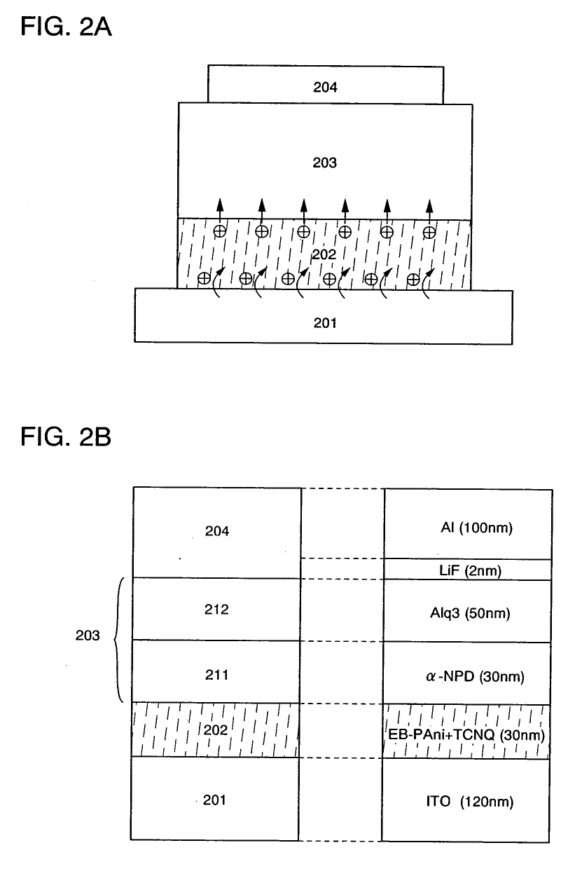

Referring now to FIGS. 2A and 2B, there is shown an electroluminescence (EL) element in accordance with Embodiment 1 of the present invention. In this case, a buffer layer 202 is formed on a first electrode 201. On the buffer layer 202, furthermore, an electroluminescence (EL) film 203 and a second electrode 204 are formed in that order. As already mentioned in the summary of the invention in this specification, the present invention has features in that the buffer layer 202 includes a combination of: a polymer compound having a conjugate on its main chain or side chain (hereinafter, referred to as conjugate polymer); and at least one selected from compounds having acceptor properties, including: a parabenzoquinone derivative represented by the general formula (1); a naphthoquinone derivative represented by the general formula (2); a tetracyanoquinodimethane derivative or a dicyanoquinodiimine represented by the general formula (3); a compound represented by the general formula (4); a compound represented by the general formula (5); a compound represented by the general formula (6); and a compound represented by the general formula (7).

Furthermore, the specific examples of the compounds having acceptor properties and represented by the general formulae (1) to (7) are represented by the following chemical formulae (A1) to (A8), respectively.

(A1 Benzoquinone Derivative)

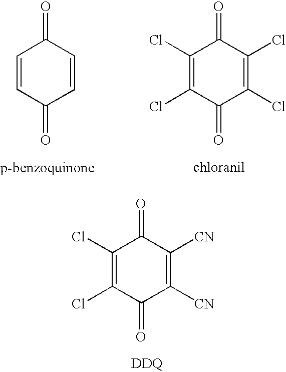

(A2: Napthoquinone Derivative)

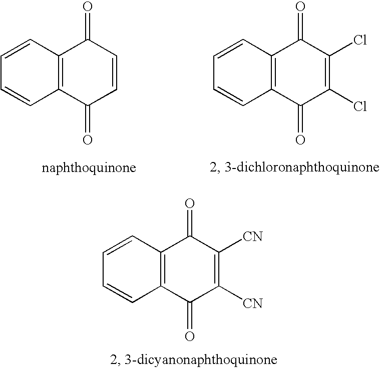

(A3: Tetracyanoquinodimetan Derivative)

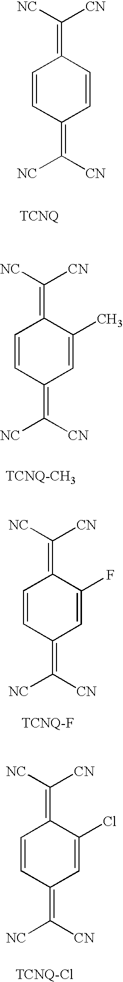

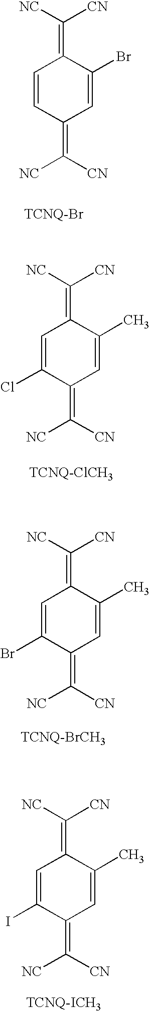

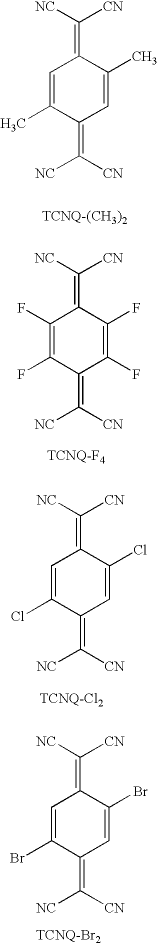

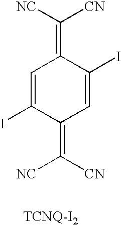

(A4: Dicyanoquinodiimine Derivative)

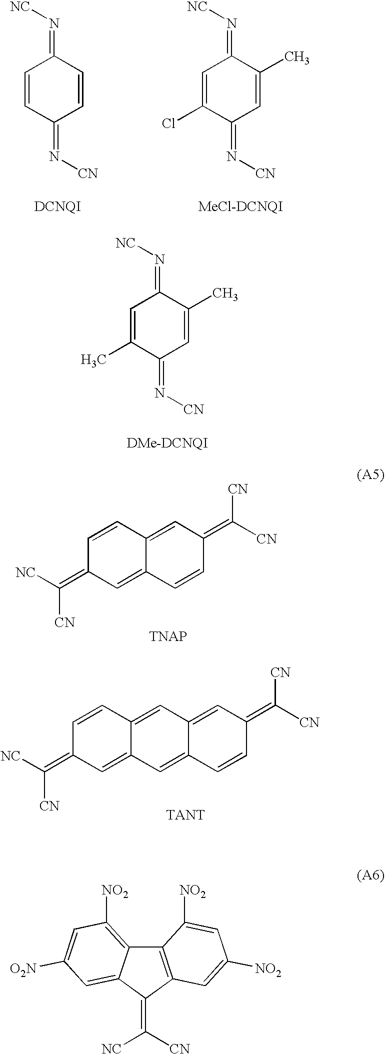

2-(2,4,5,7-Tetranitro-fluoren-9-ylidene)-malononitrile

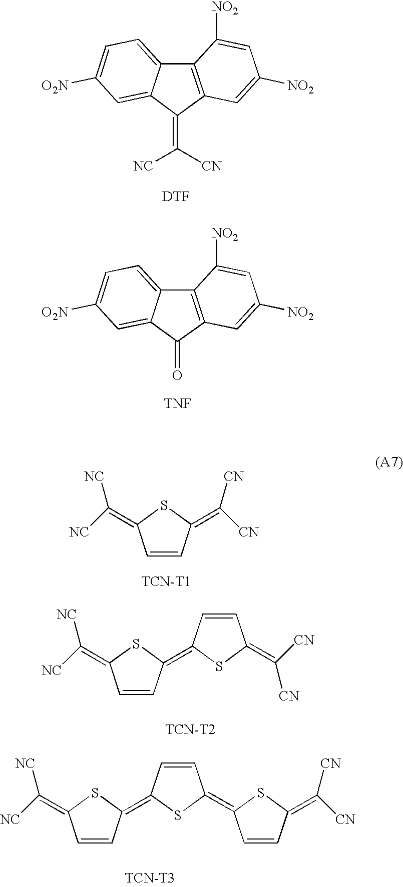

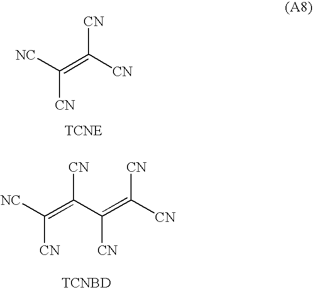

In the case of Embodiment 1, furthermore, as the buffer layer 202 is made of the material having the acceptor properties, the first electrode 201 can function as an anode. In addition, the first electrode 201 is an electrode functioning as an anode, so that it may be preferably formed of an anode material having a large work function. However, it is not always necessary to use a material having a large work function because the hole-injection properties of the first electrode 201 can be improved by the formation of the buffer layer 202.

However, for improving the element characteristics, a transparent conductive film made of indium tin oxide (ITO) is used as an anode material for forming the first electrode 201 (FIG. 2B).

Subsequently, the buffer layer 202 is formed on the first electrode 201. The buffer layer 202 may be prepared using a combination of the above-mentioned materials. Here, as shown in FIG. 2B, emeraldine base polyaniline (hereinafter, referred to as EB-PAni) is used as a conjugate polymer and tetracyanoquinodimethane (hereinafter, referred to as TCNQ) is used as an acceptor molecule. In addition, the buffer layer 202 is formed so as to be 20 to 50 nm (preferably 30 nm) in film thickness. Furthermore, as a process of forming the buffer layer 202, an application process, a spin-coating process, an inkjet process, or the like may be used.

Next, an electroluminescence film 203 is formed on the buffer layer 202. The electroluminescence film 203 may be formed of a single material or may be formed as a laminate structure made of a plurality of materials.

When the electroluminescence film 203 is formed as a laminate structure, it may be constructed of a combination of layers having the respective functions, such as a hole injection layer, a hole transporting layer, a light emitting layer, and a hole blocking layer (blocking layer), an electron transporting layer, and an electron injection layer such that the electroluminescence film 203 includes at least a layer having the light-emitting properties.

In Embodiment 1, as shown in FIG. 2B, the electroluminescence film 203 is formed as a laminate structure of a hole transporting layer 211 and an electron transporting layer 212. Specifically the hole transporting layer 211 is prepared using 4,4′-bis[N-(1-naphthyl)-N-phenyl-amino]-biphenyl (hereinafter, referred to as α-NPD) of 30 nm in film thickness as a material having the hole transporting property, while the electron transporting layer 212 is prepared using aluminum tris (8-quinolinolato) (hereinafter, referred to as Alq₃) of 50 nm in thickness as a material having the electron transporting property. Furthermore, in the case of such a laminate structure, Alq₃ used for forming the electron transporting layer 212 has the light-emitting properties.

Subsequently, a second electrode 204 is formed on the electroluminescence film 203. Furthermore, the second electrode 204 is prepared using a cathode material having a small work function (specifically, material having a work function of 3.5 eV or less) so as to be provided as an electrode functioning as a cathode. Here, the second electrode 204 may be formed as a single-layer structure formed of a single material, or as a laminate structure constructed of a plurality of materials. In Embodiment 1, as shown in FIG. 2B, there is described the formation of a cathode 204 by laminating lithium fluoride (LiF) of 2 nm in film thickness and aluminum (Al) of 100 nm in film thickness. In this case, it becomes possible to realize the formation of an electrode having two functions: a reduction in work function of the cathode 204 using the lithium fluoride (LiF) and an increase in conductivity of the cathode 204 using the aluminum (Al). Furthermore, as a cathode material, the electrode may be prepared using any of combinations of the well-known materials having smaller work functions without restriction.

As described above, a buffer layer without using water as a solvent can be prepared using a material (material for an electroluminescence element) provided as a combination of a compound (hereinafter, referred to as conjugate polymer) having a conjugate on its main chain or side chain and at least one selected from compounds having acceptor properties, including: a parabenzoquinone derivative represented by the general formula (1); a naphthoquinone derivative represented by the general formula (2); a tetracyanoquinodimethane derivative or a dicyanoquinodiimine represented by the general formula (3); a compound represented by the general formula (4); a compound represented by the general formula (5); a compound represented by the general formula (6); and a compound represented by the general formula (7). Furthermore, as the formation of such a buffer layer allows an improvement in property of carrier (hole) injection from the electrode (anode in Embodiment 1), the drive voltage of the electroluminescence element can be reduced while attaining a high reliability thereof.

[Embodiment 2]

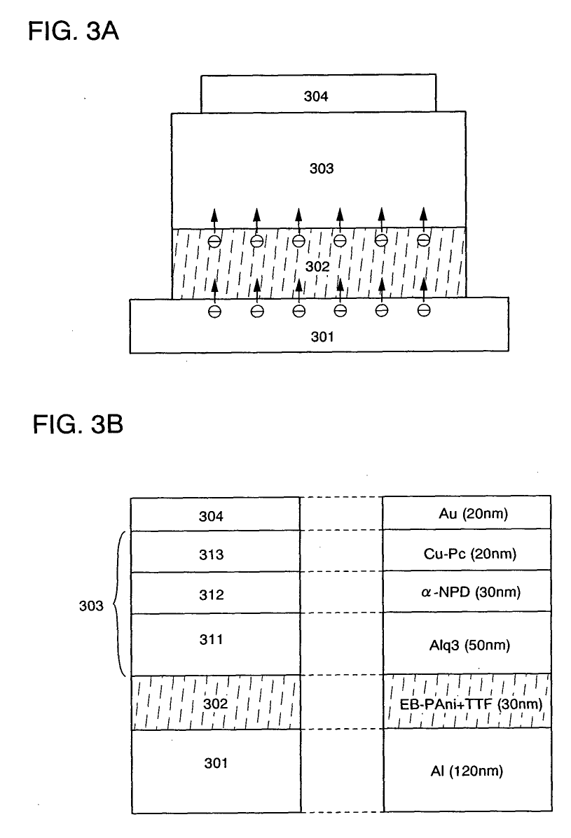

Referring now to FIGS. 3A and 3B, there is shown an electroluminescence (EL) element in accordance with Embodiment 2 of the present invention. In this case, a buffer layer 302 is formed on a first electrode 301. On the buffer layer 302, furthermore, an electroluminescence (EL) film 303 and a second electrode 304 are formed in that order. The present invention has features in that the buffer layer 302 includes a combination of: a polymer compound having a conjugate on its main chain or side chain (hereinafter, referred to as conjugate polymer); and at least one selected from compounds having donor properties, including: a compound represented by the general formula (8); a compound represented by the general formula (9); a compound represented by the general formula (10); and a compound represented by the general formula (11).

Furthermore, the specific examples of the compounds having donor properties and represented by the above general formulae (8) to (11) are represented by the following chemical formulae (D1) to (D4), respectively.

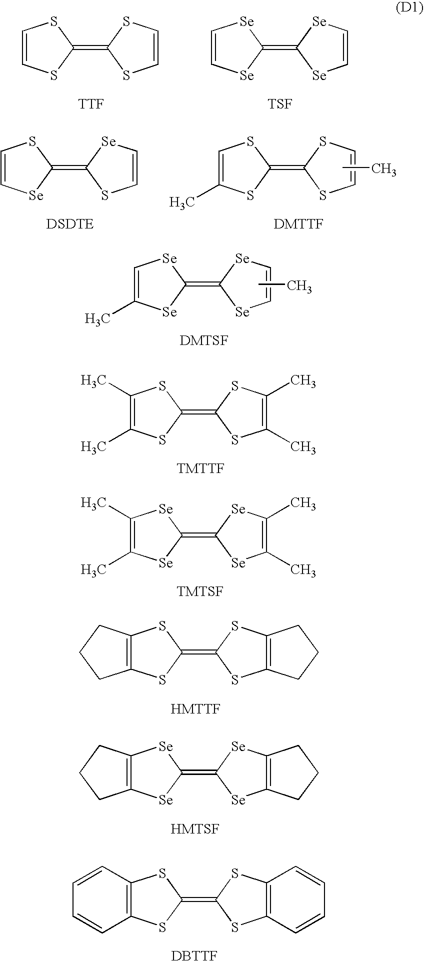

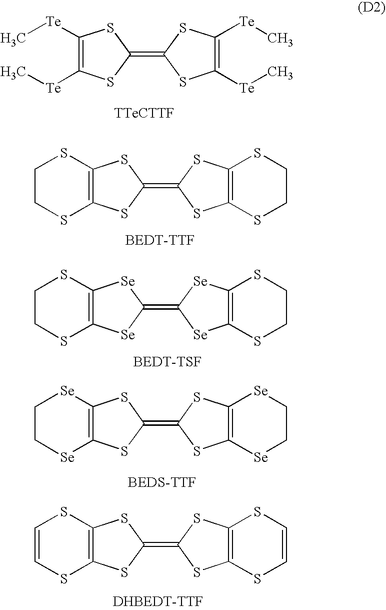

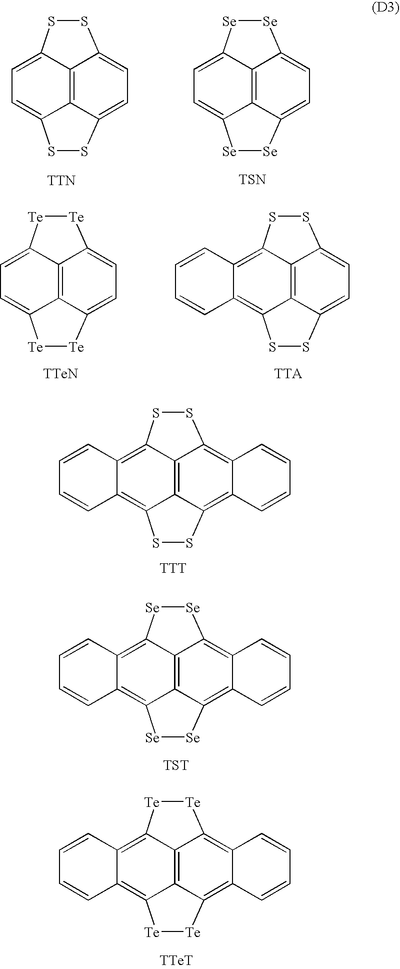

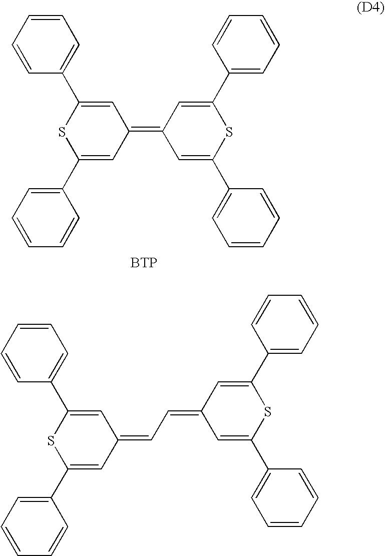

In the case of Embodiment 2, furthermore, as the buffer layer 302 is made of the material having the donor properties, the first electrode 301 can function as a cathode. In addition, the first electrode 301 is an electrode functioning as the cathode, so that it may be preferably formed of a cathode material having a small work function. However, it is not always necessary to use a material having a small work function because the electron-injection properties of the first electrode 301 can be improved by the formation of the buffer layer 302.

Furthermore, in this case, aluminum (Al) formed to have a film thickness of about 120 nm is used as a cathode material for forming the first electrode 301 (FIG. 3B).

Subsequently, the buffer layer 302 is formed on the first electrode 301. The buffer layer 302 may be prepared using a combination of the above-mentioned materials. Here, as shown in FIG. 3B, EB-PAni is used as a conjugate polymer and tetrathiofulvalene (hereinafter, referred to as TTF) is used as a donor polymer. In addition, the buffer layer 302 is formed so as to be 20 to 50 nm (preferably 30 nm) in film thickness. Furthermore, as a process of forming the buffer layer 302, an application process, a spin-coating process, an inkjet process, or the like may be used.

Next, an electroluminescence film 303 is formed on the buffer layer 302. The electroluminescence film 303 may be formed of a single material or may be formed as a laminate structure made of a plurality of materials.

When the electroluminescence film 303 is formed as a laminate structure, it may be constructed of a combination of layers having the respective functions, such as a hole injection layer, a hole transporting layer, a light emitting layer, and a hole blocking layer (blocking layer), an electron transporting layer, and an electron injection layer such that the electroluminescence film 303 includes at least a layer having the light-emitting properties.

In Embodiment 2, as shown in FIG. 3B, the electroluminescence film 303 is formed as a laminate structure of an electron transporting layer 311, a hole transporting layer 312, and a hole injection layer 313. Specifically, the electron transporting layer 311 is prepared using as a material having the electron transporting property Alq₃ of 50 nm in film thickness; the hole transporting layer 312 is prepared using as a material having the hole transporting property α-NPD of 30 nm in film thickness; and the hole injection layer 313 is prepared using as a material having the hole injection property copper phthalocyanine (hereinafter, referred to as Cu-Pc) of 20 nm in film thickness. Furthermore, in the case of such a laminate structure, Alq₃ used for forming the electron transporting layer 311 has the light-emitting properties.

Subsequently, a second electrode 304 is formed on the electroluminescence film 303. Furthermore, the second electrode 304 is prepared using an anode material having a large work function (specifically, material having a work function of 4.0 eV or more) so as to be provided as an electrode functioning as an anode. Here, the second electrode 304 may be formed as a single-layer structure formed of a single material or as a laminate structure constructed of a plurality of materials. In Embodiment 2, as shown in FIG. 3B, there is described the formation of the second electrode 304 by laminating gold (Au) of 20 nm in film thickness. Furthermore, as an anode material for use as the second electrode 304, any of combinations of the well-known materials having larger work functions may be used without restriction.

As described above, a buffer layer without using water as a solvent can be prepared using a material (material for an electroluminescence element) provided as a combination of a compound (hereinafter, referred to as conjugate polymer) having a conjugate on its main chain or side chain and at least one selected from compounds having donor properties, including: a compound represented by the general formula (8); a compound represented by the general formula (9); a compound represented by the general formula (10); and a compound represented by the general formula (11). Furthermore, as the formation of such a buffer layer allows an improvement in property of carrier (electron) injection from the electrode (cathode in Embodiment 2), the drive voltage of the electroluminescence element can be reduced while attaining a high reliability thereof.

[Embodiment 3]

In Embodiment 3, the measurements on the electrical characteristics of an electroluminescence element of the present invention are described. In this embodiment, the electroluminescence element to be used in the measurement has a structure in which a buffer layer is brought into contact with the surface of the anode as described in Embodiment 1.

Furthermore, for making a comparison between the effects of the formation of a buffer layer using the material of the present invention and those of the formation of a buffer layer without using the material of the present invention, three different kinds of electroluminescence elements were prepared under the conditions of (1) using no buffer layer, (2) using Cu-PC as a buffer layer, and (3) using a buffer layer (EB-PAni+TCNQ) of the present invention. The characteristics thereof were measured, respectively.

As the above three kinds of the electroluminescence elements, (1) in the absence of a buffer layer, an element is prepared by laminating ITO (120 nm) (anode)/α-NPD (50 nm)/Alq₃ (50 nm)/CaF (2 nm)/Al (100 nm) (cathode) one after another in that order; (2) in the case of using Cu-Pc as a buffer layer, an element is prepared by laminating ITO (120 nm) (anode)/Cu-PC (20 nm) (buffer layer)/α-NPD (30 nm)/Alq₃ (50 nm)/CaF (2 nm)/Al (100 nm) (cathode) one after another in that order; and (3) in the case of using a buffer layer (EB-PAni+TCNQ) of the present invention, an element is prepared by laminating ITO (120 nm) (anode)/(EB-PAni+TCNQ) (about 30 nm) (buffer layer)/α-NPD (30 nm)/Alq₃ (50 nm)/CaF (2 nm)/Al (100 nm) (cathode) one after another in that order.

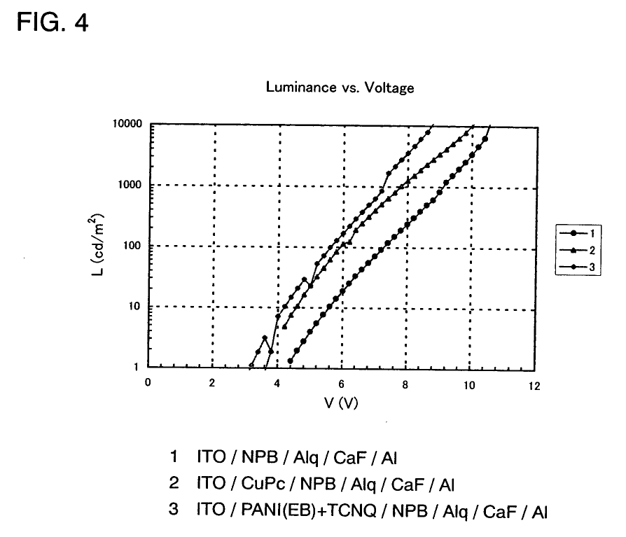

The measurements are shown in FIG. 4. The electroluminescence element (3) using the buffer layer of the present invention exhibited the lowest drive voltage, as compared with others. In addition, it is conceivable that the drive voltage of the electroluminescence element (3) using the buffer layer of the present invention is lower than the element (2) using Cu-Pc as the buffer layer because the buffer layer of the item (1) has conductivity (with the doping of acceptor) together with the flatness of the film due to the formation by a polymer film, and so on.

By using the material for the electroluminescence element of the present invention, the buffer layer without using water as the solvent can be formed unlike the case where the buffer layer is formed using the conventional polymer material. Furthermore, in the electroluminescence element formed by using the material for the electroluminescence element of the present invention, it is possible to improve the injection properties of carries from the electrode and to enhance the reliability of the element while reducing the drive voltage thereof.

What is claimed is:

1. A material for an electroluminescence element, comprising:
a polymer compound containing a conjugate on at least one of a main chain and a side chain thereof; and
a compound represented by the following general formula [1]:
[General Formula 1] 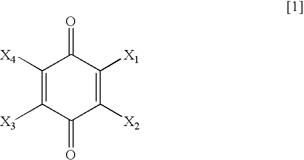
(X1 to X4: hydrogen atom, halogen atom or cyano group)

2. A material for an electroluminescence element, comprising:
a polymer compound containing a conjugate on at least one of a main chain and a side chain; and
a compound represented by the following general formula [2]:
[General Formula 2] 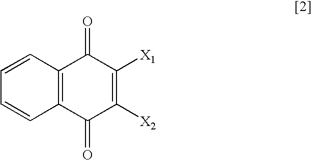
(X1 and X2: hydrogen atom, halogen atom or cyano group)

3. A material for an electroluminescence element, comprising:
a polymer compound containing a conjugate on at least one of a main chain and a side chain; and
a compound represented by the following general formula [3]:
[General Formula 3] 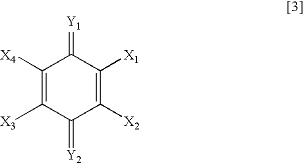
(X1 to X4: hydrogen atom, halogen atom or alkyl group
Y1 to Y2: dicyanomethlene group or cyanoimino group)

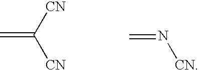

4. A material for an electroluminescence element, comprising:
a polymer compound containing a conjugate on at least one of a main chain and a side chain; and
a compound represented by the following general formula [4]:
[General Formula 4]

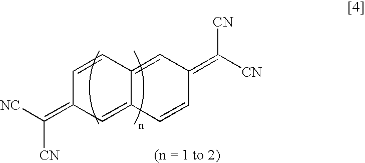

5. A material for an electroluminescence element, comprising:
a polymer compound containing a conjugate on at least one of a main chain and a side chain; and
a compound represented by the following general formula [5]:
[General Formula 5] 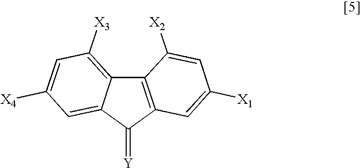
(X1 to X4: hydrogen atom or nitro group
Y: oxygen atom or dicyanomethylene group)

6. A material for an electroluminescence element, comprising:
a polymer compound containing a conjugate on at least one of a main chain and a side chain; and
a compound represented by the following general formula [6]:
[General Formula 6]

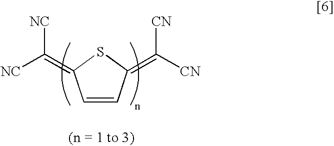

7. A material for an electroluminescence element, comprising:
a polymer compound containing a conjugate on at least one of a main chain and a side chain; and
a compound represented by the following general formula [7]:
[General Formula 7]

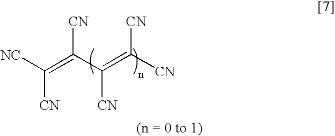

8. A material for an electroluminescence element, comprising:
a polymer compound containing a conjugate on at least one of a main chain and a side chain; and
a compound represented by the following general formula [8]:
[General Formula 8] 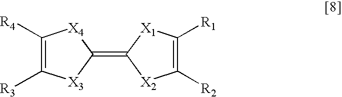
(X1 to X4: S, Se, or Te
R1 to R4: hydrogen atom, or alkyl group, or R1 and R2, or R3 and R4 may be connected with each other and form alkylene chain or condensed ring)

9. A material for an electroluminescence element, comprising:
a polymer compound containing a conjugate on at least one of a main chain and a side chain; and
a compound represented by the following general formula [9]:
[General Formula 9] 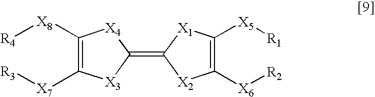
(X1 to X8: S, Se, or Te
R1 to R4: hydrogen atom, or alkyl group, or R1 and R2, or R3 and R4 may be connected with each other and form alkylene chain or olefin double bond)

10. A material for an electroluminescence element, comprising:
a polymer compound containing a conjugate on at least one of a main chain and a side chain; and
a compound represented by the following general formula [10]:
[General Formula 10] 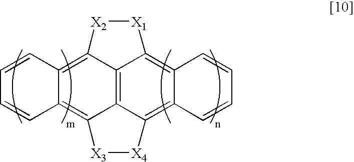
(X1 to X4: S, Se, or Te
n and m=0 to 1)

11. A material for an electroluminescence element, comprising:
a polymer compound containing a conjugate on at least one of a main chain and a side chain; and
a compound represented by the following general formula [11]:
[General Formula 11] 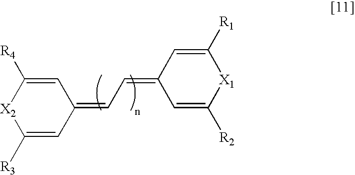
(X1 and X2: S, Se, or Te
R1 to R4: hydrogen atom, alkyl group, aryl group
n=0 to 1)

12. An electroluminescence element comprising:
an anode; a buffer layer; an electroluminescence layer; and a cathode, wherein the buffer layer is in contact with the anode, and the buffer layer comprising a material for the electroluminescence element comprising:
a polymer compound containing a conjugate on at least one of a main chain and a side chain thereof; and
a compound represented by the following general formula [1]:
[General Formula 1] 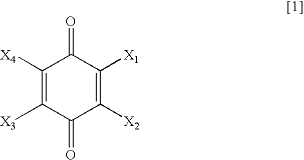
(X1 to X4: hydrogen atom, halogen atom or cyano group)

13. An electroluminescence element comprising:
an anode; a buffer layer; an electroluminescence layer; and a cathode, wherein the buffer layer is in contact with the anode, and the buffer layer comprising a material for the electroluminescence element comprising:
a polymer compound containing a conjugate on at least one of a main chain and a side chain thereof; and
a compound represented by the following general formula [2]:
[General Formula 2] 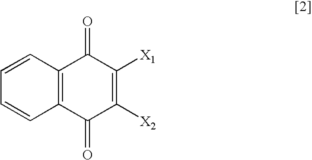
(X1 and X2: hydrogen atom, halogen atom or cyano group)

14. An electroluminescence element comprising:
an anode; a buffer layer; an electroluminescence layer; and a cathode, wherein the buffer layer is in contact with the anode, and the buffer layer comprising a material for the electroluminescence element comprising:
a polymer compound containing a conjugate on at least one of a main chain and a side chain thereof; and
a compound represented by the following general formula [3]:
[General Formula 3] 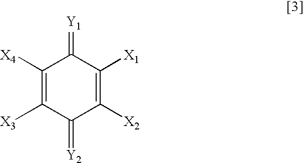
(X1 to X4: hydrogen atom, halogen atom or alkyl group
Y1 to Y2: dicyanomethlene group or cyanoimino group)

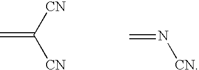

15. An electroluminescence element comprising:
an anode; a buffer layer; an electroluminescence layer; and a cathode, wherein the buffer layer is in contact with the anode, and the buffer layer comprising a material for the electroluminescence element comprising:
a polymer compound containing a conjugate on at least one of a main chain and a side chain thereof; and
a compound represented by the following general formula [4]:
[General Formula 4]

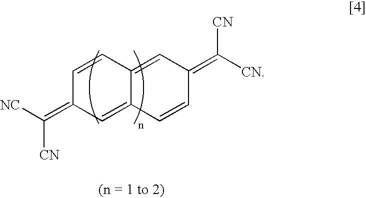

16. An electroluminescence element comprising:
an anode; a buffer layer; an electroluminescence layer; and a cathode, wherein the buffer layer is in contact with the anode, and the buffer layer comprising a material for the electroluminescence element comprising:
a polymer compound containing a conjugate on at least one of a main chain and a side chain thereof; and
a compound represented by the following general formula [5]:
[General Formula 5] 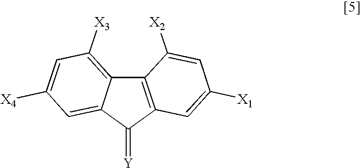
(X1 to X4: hydrogen atom or nitro group
Y: oxygen atom or dicyanomethylene group)

17. An electroluminescence element comprising:
an anode; a buffer layer; an electroluminescence layer; and a cathode, wherein the buffer layer is in contact with the anode, and the buffer layer comprising a material for the electroluminescence element comprising:
a polymer compound containing a conjugate on at least one of a main chain and a side chain thereof; and
a compound represented by the following general formula [6]:
[General Formula 6]

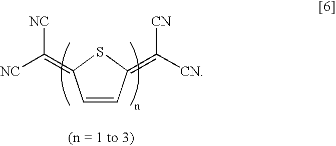

18. An electroluminescence element comprising:
an anode; a buffer layer; an electroluminescence layer; and a cathode, wherein the buffer layer is in contact with the anode, and the buffer layer comprising a material for the electroluminescence element comprising:
a polymer compound containing a conjugate on at least one of a main chain and a side chain thereof; and
a compound represented by the following general formula [7]:
[General Formula 7]

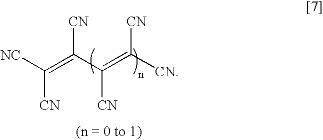

19. An electroluminescence element comprising:
an anode; a buffer layer; an electroluminescence layer; and a cathode, wherein the buffer layer is in contact with the cathode, and the buffer layer comprising a material for the electroluminescence element comprising:
a polymer compound containing a conjugate on at least one of a main chain and a side chain thereof; and
a compound represented by the following general formula [8]:
[General Formula 8] 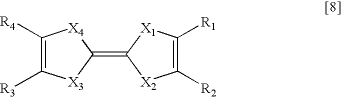
(X1 to X4: S, Se, or Te
R1 to R4: hydrogen atom, or alkyl group, or R1 and R2, or R3 and R4 may be connected with each other and form alkylene chain or condensed ring)

20. An electroluminescence element comprising:
an anode; a buffer layer; an electroluminescence layer; and a cathode, wherein the buffer layer is in contact with the cathode, and the buffer layer comprising a material for the electroluminescence element comprising:
a polymer compound containing a conjugate on at least one of a main chain and a side chain thereof; and
a compound represented by the following general formula [9]:
[General Formula 9] 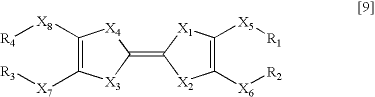
(X1 to X8: S, Se, or Te
R1 to R4: hydrogen atom, or alkyl group, or R1 and R2, or R3 and R4 may be connected with each other and form alkylene chain or olefin double bond)

21. An electroluminescence element comprising:
an anode; a buffer layer; an electroluminescence layer; and a cathode, wherein the buffer layer is in contact with the cathode, and the buffer layer comprising a material for the electroluminescence element comprising:
a polymer compound containing a conjugate on at least one of a main chain and a side chain thereof; and
a compound represented by the following general formula [10]:
[General Formula 10] 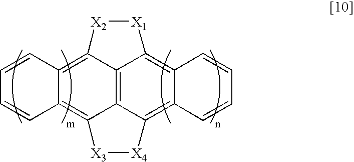
(X1 to X4: S, Se, or Te
n and m=0 to 1)

22. An electroluminescence element comprising:
an anode; a buffer layer; an electroluminescence layer; and a cathode, wherein the buffer layer is in contact with the cathode, and the buffer layer comprising a material for the electroluminescence element comprising:
a polymer compound containing a conjugate on at least one of a main chain and a side chain thereof; and
a compound represented by the following general formula [11]:
[General Formula 11] 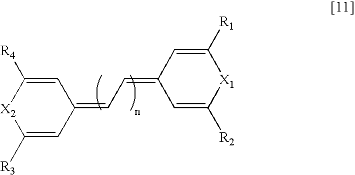
(X1 and X2: S, Se, or Te
R1 to R4: hydrogen atom, alkyl group, aryl group
n=0 to 1)

23. A material for an electroluminescence element according to any one of claims 1 to 22, wherein the polymer compound containing the conjugate on the main chain or the side chain thereof has redox properties.

24. A material for an electroluminescence element according to any one of claims 1 to 22, wherein the polymer compound containing the conjugate on the main chain or the side chain thereof comprises emeraldine base polyaniline.
